(19) United States
(12) Patent Application Publication
(10) Pub. No.: US 2026/0255622 A1
(43) Pub. Date: Aug. 27, 2026

(54) SCHOTTKY DIODE AND MANUFACTURING METHOD THEREOF

(71) Applicant: ProAsia Semiconductor Corporation, Hsinchu City (TW)

(72) Inventors: Ming-Chi Kuo, Hsinchu City (TW); I-Tai Li, Hsinchu City (TW)

(21) Appl. No.: 19/059,884

(22) Filed: Feb. 21, 2025

(51) Int. Cl. H10D 8/60; H10D 8/01; H10D 62/00; H10D 62/10; H10D 62/832

(52) U.S. Cl. CPC H10D 8/60; H10D 8/051; H10D 62/054; H10D 62/111; H10D 62/8325

(57) ABSTRACT

A Schottky diode and a manufacturing method thereof are provided. The Schottky diode comprises a substrate, a first conductive type epitaxial layer, a plurality of trench structures, a plurality of second conductive type heavily-doped barrier regions and a plurality of second conductive type doped regions. The first conductive type epitaxial layer is disposed on the substrate, and a plurality of trench structures are disposed in the first conductive type epitaxial layer. Each of the second conductivity type heavily-doped barrier regions are correspondingly disposed at the bottom of each trench structure, and each of the second conductivity type doping regions are correspondingly disposed on the side walls of each trench structure, so that a plurality of super junctions are formed between each second conductivity type doped region and the first conductivity type epitaxial layer between each trench structure.

### BACKGROUND OF THE INVENTION

### Field of the Invention

The present invention relates to a Schottky diode and a manufacturing method thereof, in particular to a Schottky diode for reducing leakage current and forward voltage, and a manufacturing method thereof.

### Descriptions of the Related Art

Schottky diodes are widely used in various applications due to their advantages such as low forward voltage, fast switching speed, and low reverse recovery time. For example: (1) power supply rectification: Schottky diodes are often used as rectifiers in power supply circuits because their low forward voltage drop reduces power loss and improves efficiency; (2) voltage clamping: they are used in clamping circuits to protect sensitive components from voltage spikes by limiting the voltage to a specific level; (3) radio frequency (RF) applications: due to their fast switching speed, Schottky diodes are often used in RF mixers and detectors, where high-frequency signal processing is required; (4) solar cell applications: Schottky diodes prevent reverse current flow in solar cell systems, thereby improving overall efficiency; and (5) logic circuits: in digital logic circuits, Schottky diodes are used to speed up signal transmission, especially in TTL (transistor-transistor logic) circuits.

Due to these characteristics, Schottky diodes are widely used in high-efficiency power management, fast signal processing, and protection circuits. On the other hand, trench structures have been extensively adopted in silicon-based transistor devices and are widely recognized for their ability to reduce ON-state resistance. However, conventional single trench structures suffer from long-term reliability issues due to electric field concentration at the trench bottoms. Therefore, optimizing the Schottky diode structure to reduce leakage current and forward voltage, thereby enhancing device performance, remains a critical challenge in the industry.

### SUMMARY OF THE INVENTION

The main objective of the present invention is to provide an innovative Schottky diode and a manufacturing method thereof. The Schottky diode utilizes a mask of forming P-type heavily-doped barrier regions for creating multiple trench structures and forming super junctions. This structure mitigates the issue of electric field concentration at the trench bottoms, effectively reducing leakage current and forward voltage, and thereby improving device performance.

To achieve the above objective, the present invention discloses a Schottky diode which comprises a substrate, a first conductive type epitaxial layer, a plurality of trench structures, a plurality of second conductive type heavily-doped barrier regions and a plurality of second conductive type doped regions. The first conductive type epitaxial layer is disposed on the substrate, and a plurality of trench structures are disposed in the first conductive type epitaxial layer. Each of the second conductivity type heavily-doped barrier regions are correspondingly disposed at the bottom of each trench structure, and each of the second conductivity type doping regions are correspondingly disposed on the side walls of each trench structure, so that a plurality of super junctions are formed between each second conductivity type doped region and the first conductivity type epitaxial layer between each trench structure.

In one embodiment of a Schottky diode of the present invention, each of the second conductive type doped regions has aluminum doping with a doping concentration of 1~10E18 (cm⁻³ ).

In one embodiment of a Schottky diode of the present invention, each of the second conductive type heavily-doped barrier regions has aluminum doping with a doping concentration of 1E18~5E19 (cm⁻³).

In one embodiment of a Schottky diode of the present invention, the substrate is a first conductive type heavily-doped silicon carbide substrate.

In one embodiment of a Schottky diode of the present invention, the Schottky diode further comprises an anode metal covering the first conductive type epitaxial layer and each of the trench structures so that Schottky contact is formed between the anode metal and the first conductive type epitaxial layer, and ohmic contact is formed between the anode metal and each of the second conductive type heavily-doped barrier regions and each of the second conductive type doped regions.

In one embodiment of a Schottky diode of the present invention, the anode metal is selected from one of the group consisting of aluminum, chromium, gold, platinum, titanium, cobalt and nickel and combinations thereof.

To achieve the above objective, the present invention discloses a manufacturing method of a Schottky diode comprising the following steps: providing a first conductive type epitaxial layer disposed on a substrate, providing a plurality of trench structures disposed in the first conductive type epitaxial layer, providing a plurality of second conductive type heavily-doped barrier regions correspondingly disposed at the bottom of each of the trench structures, and providing a plurality of second conductive type doped regions correspondingly disposed on the side walls of each of the trench structures so that a plurality of super junctions are formed between each of the second conductivity type doped regions and the first conductivity type epitaxial layer between each of the trench structures.

In one embodiment of a method of manufacturing a Schottky diode of the present invention, the step of providing a first conductive type epitaxial layer is to implant nitrogen (N) or phosphorus (P) with a doping concentration of 1E14~1E16 (cm⁻³) after providing a silicon carbide epitaxial layer on the substrate.

In one embodiment of a method of manufacturing a Schottky diode of the present invention, the step of providing a plurality of trench structures is to remove a portion of the first conductive type epitaxial layer by using a patterned mask disposed on the first conductive type epitaxial layer.

In one embodiment of a method of manufacturing a Schottky diode of the present invention, the step of providing a plurality of second conductive type heavily-doped barrier regions is to use the patterned mask to perform ion implantation on the bottom of each of the trench structures by implanting aluminum with a doping concentration of 1E18~5E19 (cm⁻³).

In one embodiment of a method of manufacturing a Schottky diode of the present invention, the step of providing a plurality of second conductive type doped regions is to use the patterned mask to perform tilt ion implantation to the side walls of each of the trench structures by implanting aluminum with an ion implantation dose of 1~10E13 (cm⁻²) and an ion implantation energy of 20~100 (keV).

In one embodiment of a method of manufacturing a Schottky diode of the present invention, the tilt ion implantation is to implant ions with an implantation tilt angle of 30°~45° between a vertical normal.

In one embodiment of a method of manufacturing a Schottky diode of the present invention, the manufacturing method further comprises a step of providing an anode metal covering the first conductive type epitaxial layer and each of the trench structures so that Schottky contact is formed between the anode metal and the first conductive type epitaxial layer, and ohmic contact is formed between the anode metal and each of the second conductive type heavily-doped barrier regions and each of the second conductive type doped regions.

In one embodiment of a method of manufacturing a Schottky diode of the present invention, the step of providing an anode metal is to provide a material selected from one of the group consisting of aluminum, chromium, gold, platinum, titanium, cobalt and nickel and combinations thereof.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 to FIG. 5 are schematic diagrams illustrating the manufacturing process of a Schottky diode according to an embodiment of the present invention; and

FIG. 6 is a schematic diagram illustrating the manufacturing process flow of the Schottky diode according to an embodiment of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

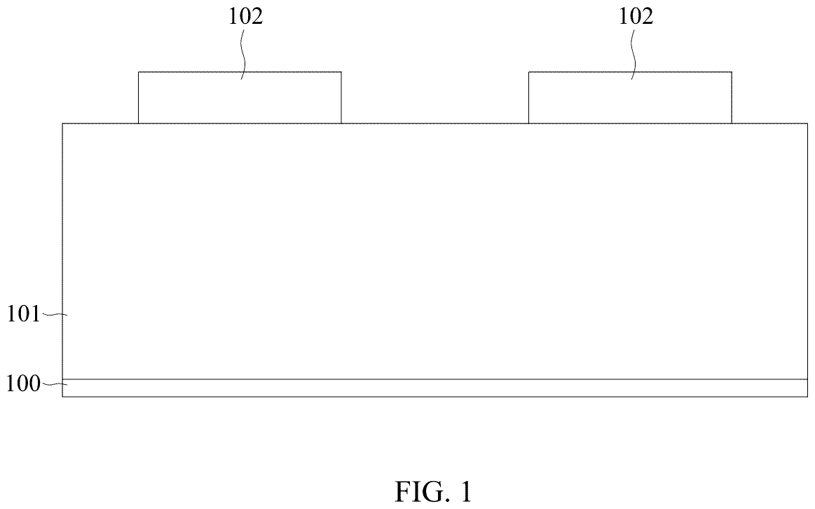

Please refer to FIG. 1 to FIG. 5, which illustrate cross-sectional schematic diagrams of the manufacturing process of a Schottky diode according to an embodiment of the present invention. Specifically, this Schottky diode is a junction barrier Schottky (JBS) diode, as described in detail below. The Schottky diode includes a substrate 100. In this embodiment, the substrate 100 is a first conductivity type silicon carbide substrate, for example, an N-type heavily doped silicon carbide substrate, providing a low-resistance channel. An epitaxial layer 101 of the first conductivity type is epitaxially formed on the substrate 100. The first conductivity type epitaxial layer 101 may be, but is not limited to, an N-type lightly doped silicon carbide epitaxial layer, serving as an N-type drift layer. Specifically, the first conductivity type epitaxial layer 101 is formed by epitaxially growing a silicon carbide epitaxial layer on the substrate 100, followed by implantation of nitrogen (N) or phosphorus (P), with a doping concentration ranging from 1E14 to 1E16 cm⁻³ and a thickness of several to tens of micrometers (μm). Notably, the N-type drift layer functions as the high-voltage sustaining region of the Schottky diode, where a thicker layer and a lower doping concentration enable higher voltage endurance. In a specific embodiment, the thickness and doping concentration of the first conductivity type epitaxial layer 101 can be designed according to the voltage endurance requirements of the Schottky diode. Next, a photoresist is deposited on the first conductivity type epitaxial layer 101. After a photolithography and etching process, a patterned mask 102 is finally formed on the first conductivity type epitaxial layer 101, as shown in FIG. 1.

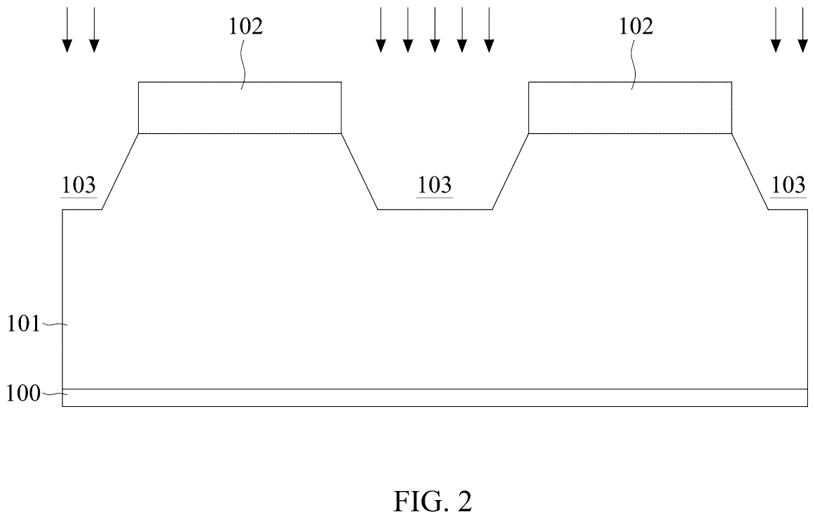

Please refer to FIG. 2. Using the patterned mask 102 as an etching mask, the first conductivity type epitaxial layer 101 is etched to remove a portion of the first conductivity type epitaxial layer 101, forming multiple trench structures 103. The depth of the trench structures 103 can be adjusted according to application requirements to optimize the trade-off between conduction resistance and voltage endurance. Moreover, the trench structures 103 in this Schottky diode device can also serve as alignment marks in subsequent conventional processes, eliminating the need for creating an additional zero-layer mask for alignment mark formation.

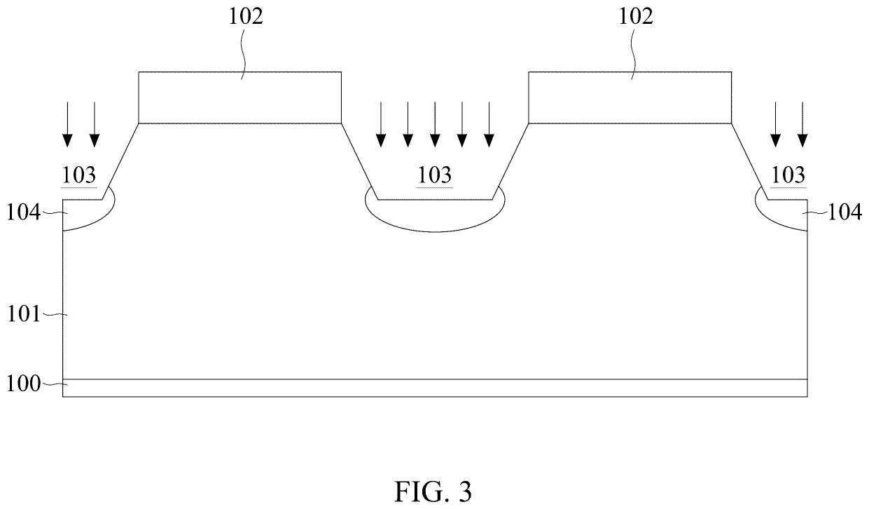

Next, please refer to FIG. 3. Using the patterned mask 102, an ion implantation process is performed on the bottom of each trench structure 103 to form multiple second conductivity type heavily-doped barrier regions 104 correspondingly disposed at the bottoms of the trench structures 103. This forms localized PN junctions to suppress the reverse leakage current of the Schottky diode and enhance its voltage endurance. In a specific embodiment, the second conductivity type heavily-doped barrier regions 104 are P-type heavily-doped barrier regions, with typical P-type dopants being aluminum (Al) or boron (B). Preferably, the present invention employs aluminum (Al) as the primary P-type dopant, with an ion implantation doping concentration of approximately 1E18 to 5E19 cm⁻³.

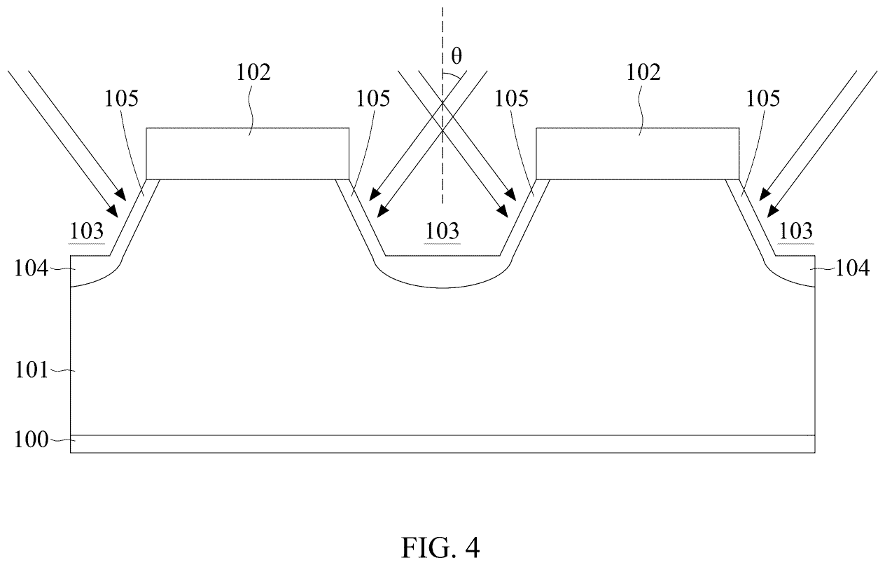

Please refer to FIG. 4. A tilted ion implantation process is then performed using the patterned mask 102, implanting ions at an angle into the sidewalls of each trench structure 103, thereby forming multiple second conductivity type doped regions 105 on the sidewalls of the trench structures 103. As shown in FIG. 4, in a specific embodiment, the tilted ion implantation is performed at an implantation tilt angle θ between 30° and 45° with respect to the vertical normal. The tilted ion implantation uses P-type ions, such as aluminum (Al) ions, with an ion implantation dose of 1E13 to 1E14 cm⁻² and an ion implantation energy of 20 to 100 keV, resulting in aluminum doping in the second conductivity type doped regions 105 with a doping concentration of 1E18 to 1E19 cm⁻³. It should be noted that a plurality of super junctions, comprising alternating P-type heavily-doped and N-type lightly-doped regions, are formed between the first conductivity type epitaxial layer 101 and the second conductivity type doped regions 105 between adjacent trench structures 103. These alternating P-type and N-type doped regions help reduce the surface electric field, create an uniform electric field, lower leakage current, and enhance voltage endurance. Additionally, the alternating P-type and N-type super junctions, combined with an increased doping concentration (i.e., enhancing carrier concentration) in the first conductivity type epitaxial layer 101, can reduce the On-state resistance and decrease the forward voltage (Vf), thereby improving conduction efficiency.

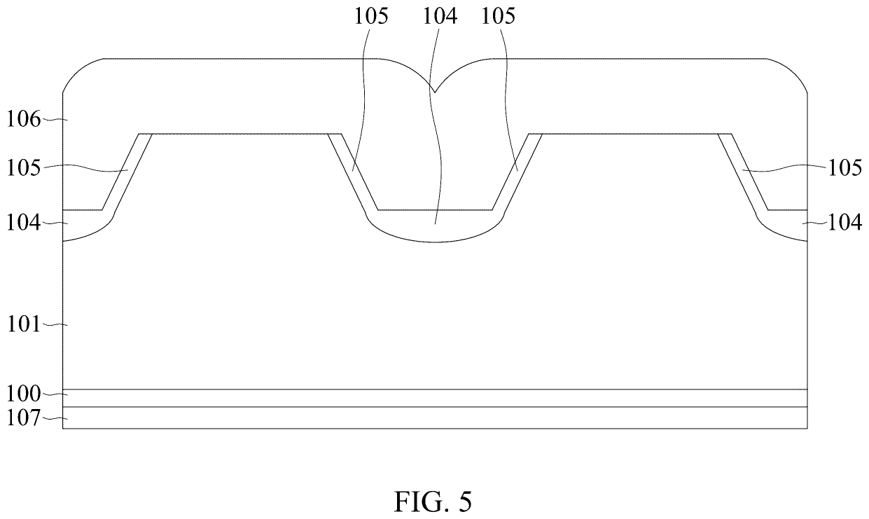

Finally, as shown in FIG. 5, after removing the patterned mask 102, the metal contact regions at the front and back ends of the device are defined, forming an anode metal 106 and a cathode metal 107, respectively. Notably, the anode metal 106 covers the first conductivity type epitaxial layer 101 and the trench structures 103, forming a Schottky contact with the upper surface of the first conductivity type epitaxial layer 101 and an ohmic contact with the second conductivity type heavily-doped barrier regions 104 and the second conductivity type doped regions 105 at the bottoms of the trench structures 103. On the other hand, the cathode metal 107 covers the backside of the substrate 100 and forms an ohmic contact with the backside of the substrate 100. Furthermore, the materials of the anode metal 106 and the cathode metal 107 are selected from one of the group consisting of aluminum, chromium, gold, platinum, titanium, cobalt, and nickel and their combinations, to meet the requirements of the aforementioned Schottky and ohmic contacts.

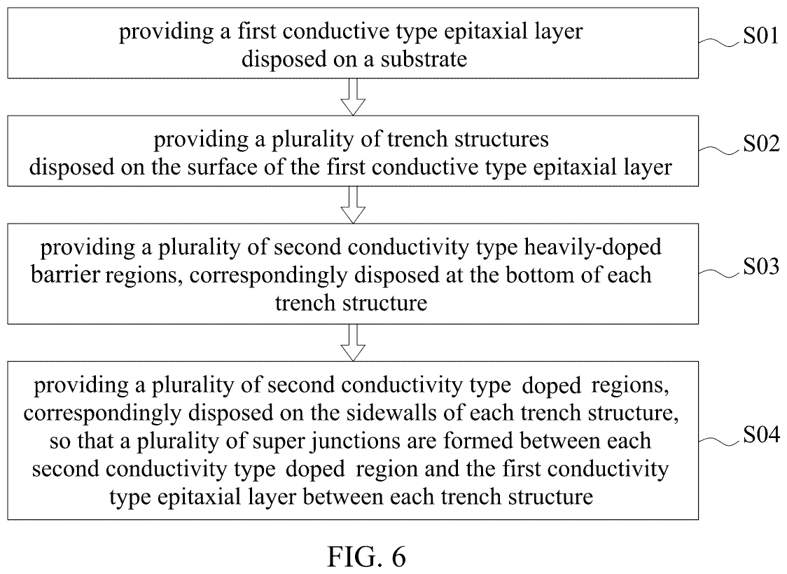

Please refer to FIG. 6, which illustrates a flowchart of the manufacturing process of a Schottky diode according to the present invention. First, in step S01, a first conductivity type epitaxial layer is provided on a substrate. In step S02, multiple trench structures are formed on the surface of the first conductivity type epitaxial layer. Next, in step S03, multiple second conductivity type heavily-doped barrier regions are formed correspondingly at the bottoms of the trench structures. Finally, in step S04, multiple second conductivity type doped regions are formed correspondingly on the sidewalls of the trench structures, forming multiple super junctions between the first conductivity type epitaxial layer and the trench structures. The descriptions of related components in the aforementioned process steps can be referred to in the above content and will not be repeated here.

In summary, the present invention incorporates trench structures in the JBS diode and forms alternating P-type and N-type super junctions between the trench structures and the drift layer. This configuration provides a uniformly distributed electric field, alleviating electric field concentration issues at the trench bottoms and enhancing the device's voltage endurance. Furthermore, it allows for a higher doping concentration in the drift region, reducing On-state resistance and preventing breakdown under high-voltage conditions, thereby improving device reliability. Under reverse bias conditions, the uniform electric field within the super junctions effectively suppresses reverse leakage current.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A Schottky diode, comprising:
a substrate;
a first conductive type epitaxial layer, disposed on the substrate;
a plurality of trench structures, disposed in the first conductive type epitaxial layer;
a plurality of second conductive type heavily-doped barrier regions, correspondingly disposed at the bottom of each of the trench structures; and
a plurality of second conductive type doped regions, correspondingly disposed on the side walls of each of the trench structures, so that a plurality of super junctions are formed between each of the second conductivity type doped regions and the first conductivity type epitaxial layer between each of the trench structures.

2. The Schottky diode of claim 1, wherein each of the second conductive type doped regions has aluminum doping with a doping concentration of 1~10E18 (cm⁻³).

3. The Schottky diode of claim 1, wherein each of the second conductive type heavily-doped barrier regions has aluminum doping with a doping concentration of 1E18~5E19 (cm⁻³).

4. The Schottky diode of claim 1, wherein the substrate is a first conductive type heavily-doped silicon carbide substrate.

5. The Schottky diode of claim 1, further comprising an anode metal covering the first conductive type epitaxial layer and each of the trench structures so that Schottky contact is formed between the anode metal and the first conductive type epitaxial layer, and ohmic contact is formed between the anode metal and each of the second conductive type heavily-doped barrier regions and each of the second conductive type doped regions.

6. The Schottky diode of claim 5, wherein the anode metal is selected from one of the group consisting of aluminum, chromium, gold, platinum, titanium, cobalt and nickel and combinations thereof.

7. A manufacturing method of a Schottky diode, comprising:
providing a first conductive type epitaxial layer, disposed on a substrate;
providing a plurality of trench structures, disposed in the first conductive type epitaxial layer;
providing a plurality of second conductive type heavily-doped barrier regions, correspondingly disposed at the bottom of each of the trench structures; and
providing a plurality of second conductive type doped regions, correspondingly disposed on the side walls of each of the trench structures, so that a plurality of super junctions are formed between each of the second conductivity type doped regions and the first conductivity type epitaxial layer between each of the trench structures.

8. The manufacturing method of a Schottky diode of claim 7, wherein the step of providing a first conductive type epitaxial layer is to implant nitrogen (N) or phosphorus (P) with a doping concentration of 1E14~1E16 (cm⁻³) after providing a silicon carbide epitaxial layer on the substrate.

9. The manufacturing method of a Schottky diode of claim 7, wherein the step of providing a plurality of trench structures is to remove a portion of the first conductive type epitaxial layer by using a patterned mask disposed on the first conductive type epitaxial layer.

10. The manufacturing method of a Schottky diode of claim 9, wherein the step of providing a plurality of second conductive type heavily-doped barrier regions is to use the patterned mask to perform ion implantation on the bottom of each of the trench structures by implanting aluminum with a doping concentration of 1E18~5E19 (cm⁻³).

11. The manufacturing method of a Schottky diode of claim 9, wherein the step of providing a plurality of second conductive type doped regions is to use the patterned mask to perform tilt ion implantation to the side walls of each of the trench structures by implanting aluminum with an ion implantation dose of 1~10E13 (cm⁻²) and an ion implantation energy of 20~100 (keV).

12. The manufacturing method of a Schottky diode of claim 11, wherein the tilt ion implantation is to implant ions with an implantation tilt angle of 30°~45° between a vertical normal.

13. The manufacturing method of a Schottky diode of claim 7, further comprising a step of providing an anode metal covering the first conductive type epitaxial layer and each of the trench structures so that Schottky contact is formed between the anode metal and the first conductive type epitaxial layer, and ohmic contact is formed between the anode metal and each of the second conductive type heavily-doped barrier regions and each of the second conductive type doped regions.

14. The manufacturing method of a Schottky diode of claim 13, wherein the step of providing an anode metal is to provide a material selected from one of the group consisting of aluminum, chromium, gold, platinum, titanium, cobalt and nickel and combinations thereof.
